(19) United States
(12) Patent Application Publication
(10) Pub. No.: US 2017/0044656 A1
(43) Pub. Date: Feb. 16, 2017

(54) PROCESS FOR MANUFACTURING A GLASS SUBSTRATE EQUIPPED WITH PRINTED PATTERNS AND A PROTECTIVE UNDERLAYER FOR ONE-WAY VISION

(71) Applicant: SAINT-GOBAIN GLASS FRANCE, Courbevoie (FR)

(72) Inventors: Kamel CHAHBOUNE, Soissons (FR); Elodie DUCOURTHIAL, Compiegne (FR)

(73) Assignee: SAINT-GOBAIN GLASS FRANCE, Courbevoie (FR)

(21) Appl. No.: 15/305,547

(22) PCT Filed: Apr. 21, 2015
(86) PCT No.: PCT/FR2015/051079

§ 371 Date: Oct. 20, 2016

(30) Foreign Application Priority Data
Apr. 24, 2014 (FR) 1453709

(51) Int. Cl. C23C 14/10; C23C 14/35; C03C 17/34; C03C 17/00; C03C 8/14; C03C 17/04

(52) U.S. Cl. CPC C23C 14/10; C03C 8/14; C03C 17/04; C03C 17/3417; C03C 17/002; C23C 14/35; C03C 2205/02; C03C 2217/213; C03C 2217/228; C03C 2217/216; C03C 2218/119; C03C 2218/156; C03C 2217/485; C03C 2217/477

(57) ABSTRACT

The present invention relates to a process for manufacturing a one-way vision glass pane comprising one or more separate enamel patterns composed of a number of exactly aligned layers, characterized in that:

a) at least one protective layer based on oxides, having a thickness greater than or equal to 10 nm, is deposited on the glass substrate,
b) at least two layers of different compositions are deposited on the protective layer, the composition of one containing at least one mineral pigment and being free of glass frit, the composition of the other being an enamel containing at least one glass frit and at least one mineral pigment having a color different from that of the layer free of glass frit, the layer free of glass frit being deposited over all or some of the surface of the pane and the layer of enamel being deposited by screen printing in the shape of the desired pattern(s),
c) the pane coated with said layers is heated at a temperature sufficient to fire the enamel, and
d) the pigments not fixed by the enamel that are located outside of the pattern(s) are removed, the particles of pigment(s) and the particles of glass frit(s) having a similar size, in particular a particle size distribution such that 50% of the particles have a size of less than 7 μm.

The present invention relates to the field of printed glass substrates comprising enamel-based patterns.

Printed glass substrates are used in various applications, for decorative and/or functional purposes, such as for example as glazing for buildings or automobiles. Patent application WO 2012/172269 describes a process for manufacturing a one-way vision glass pane. This type of glazing unit enables an observer located inside a building or vehicle to have normal vision of the outside surroundings, whilst an observer located outside will be unable to see inside. Such glazing units are obtained by applying a first layer of pigments, often of black color, free of glass frit, directly to the glass substrate in the shape of the desired patterns, then by depositing a second layer of enamel comprising a glass frit and pigments of a light color other than black, for example white, over all of the patterns. The assembly is brought to a temperature sufficient to fire the enamel. During the enamel firing phase, the glass frit present in the second layer of enamel softens and bonds to the glass of the substrate, thereby retaining the black pigments. After firing, the black pigments deposited outside of the patterns, and not fixed by the enamel, are removed using an appropriate treatment, for example by vacuum suction or by applying an air or water jet. In order to prevent the migration of the black pigments into a layer of light color such as white and thus prevent the white from being perceived with a grayish tint, application WO 2012/172269 proposes on the one hand to use pigments and glass frits having particles of a similar size, and on the other hand to deposit a thicker thickness of the second layer of enamel, the thickness of the layer of pigments before firing or heating being between 4 and 15 μm and the thickness of the layer of enamel before firing or heating being between 20 and 100 μm. The step of fixing pigments to the glass is carried out by firing which is generally performed between 600 and 700° C. However, it turns out that certain samples remain tinted after firing, especially due to the migration of certain compounds of the black pigments, to locations which have not been covered by the white enamel. This tinted appearance is even more pronounced when the temperature at which the firing was carried out is high. Even after cleaning the glass substrate, this black coloration does not disappear and is probably explained by migration of the black pigments to the surface of the glass. The tint of the glass is not however permanent and it disappears by chemical etching or leaching, for example by acid etching. However, this variation of tint as a function of the firing and of the time does not make it possible to obtain a product that is stable throughout the service life of the product. The present invention makes it possible to eliminate the drawbacks explained above.

The present invention relates to a process for manufacturing a one-way vision glass pane comprising one or more separate enamel patterns composed of a number of exactly aligned layers, according to which process:
a) at least one protective layer based on oxides, having a thickness greater than or equal to 10 nm, is deposited on the glass substrate,
b) at least two layers of different compositions are deposited on the protective layer, the composition of one of the layers containing at least one mineral pigment and being free of glass frit, the composition of the other layer being an enamel containing at least one glass frit and at least one mineral pigment having a color different from that of the layer free of glass frit, the layer free of glass frit being deposited over all or some of the surface of the pane and the layer of enamel being deposited by screen printing in the shape of the desired pattern(s),
C) the pane coated with said layers is heated at a temperature sufficient to fire the enamel, and
d) the pigments not fixed by the enamel that are located outside of the pattern(s) are removed, the particles of pigment(s) and the particles of glass frit(s) having a similar size, in particular a particle size distribution such that 50% of the particles have a size of less than 7 μm.

According to a first embodiment, during step b), the layer free of glass frit is deposited on the protective layer over a thickness of between 4 and 15 μm, over all or part of the surface of the pane, then the layer of enamel is deposited by screen printing over a thickness of between 10 and 100 μm in the shape of the desired pattern(s).

According to another embodiment, during step b), the layer of enamel is deposited on the protective layer over a thickness of between 10 and 100 μm in the shape of the desired pattern(s), then the layer free of glass frit is deposited over a thickness of between 4 and 30 μm, over all or part of the surface of the pane.

The thicknesses given to each of the layers deposited during step b) are measured on wet layers, i.e. before the firing step c).

Each successive deposition of the layers carried out in step b) is advantageously followed by a heat treatment step before depositing the second layer. The temperature of this treatment varies generally from 70 to 150° C., and preferably is at least equal to 110° C. The treatment may be carried out according to a method known to a person skilled in the art, for example by means of infrared lamps.

The fact of depositing a protective layer on the glass substrate, before depositing the mineral pigment and the enamel layer advantageously makes it possible to improve, or even eliminate the gray tint that could be observed after firing in the processes of the prior art. The protective layer acts as a barrier layer during the firing step and prevents the migration of the pigment to the substrate and consequently the undesired coloration thereof.

Preferably, the protective layer deposited in step a) of the process according to the invention is a layer of silicon oxide or of titanium oxide. More preferably still, the protective layer is a layer of silicon oxide. It may for example be deposited by magnetron sputtering. This type of layer has the advantage of being transparent and neutral and consequently of not modifying the coloration of the substrate, or the optical properties of the substrate coated with the protective layer. The deposition by magnetron sputtering makes it possible to obtain a sufficiently dense layer that performs its protective layer role well.

The protective layer has the advantage of being durable over time and resistant to aging.

Preferably, the thickness of the protective layer is between 10 and 150 nm. More preferably still, it is between 20 and 100 nm.

According to one embodiment, step a) of the process according to the invention may consist in depositing two successive layers based on oxides of different nature and thickness.

Depending on the protective layer chosen, it is possible to give a slight coloration to the coated substrate. Thus, the deposition of a protective layer made of titanium oxide makes it possible to give a slightly yellow coloration to the coated substrate. Unlike the undesired gray tint observed in the processes of the prior art, this coloration is uniform irrespective of the firing temperature of the enamel and is stable over time.

The deposition of the layer of pigments free of glass frit carried out in step b) may take place by any means known to a person skilled in the art, in particular by flat or rotary screen printing.

The mineral pigment is preferably selected from the pigments that make it possible to impart a black color after the firing step. By way of example, mention may be made of pigments based on chromium, iron, manganese, copper and/or cobalt, especially in the form of oxides or sulfides. Although chromium-based pigments make it possible to have an intense black color, they are not preferred due to problems linked to their potential toxicity and their recycling. Thus, preferably, the mineral pigment used in the layer free of glass frit is free of chromium.

Advantageously, the black mineral pigment has a lightness L*, such as defined in the CIE (1931) Lab color space, that is 15 or less and preferably 10 or less, as measured for the final glass pane.

When the deposition is carried out by screen printing, the pigment is generally mixed with an organic medium allowing the viscosity to be adjusted in order for the mixture to be able to pass through the meshes of the screen-printing screen correctly. The viscosity of the mixture generally varies from 80 to 120 poise and is preferably about 100 poise.

The organic medium also has the function of temporarily fixing the pigments until the following layer of enamel composition is applied.

The organic medium must be able to be removed at the start of the step of firing the enamel in order to stop pores and cracks appearing in the final enamel. It is generally an organic solvent, preferably based on a mixture of “heavy” or terpene alcohols (“pine oil”), possibly combined with one or more resins that increase the strength with which the pigment is temporarily fixed to the surface of the pane.

Preferably, the thickness of the layer of pigments free of glass frit deposited on the glass pane varies from 6 to 10 μm.

The deposition of the enamel composition is carried out by screen printing. Screen printing is a well-known printing technique that uses a screen-printing screen consisting of a fabric on which the pattern(s) to be printed is (are) reproduced and a doctor blade allowing enough shear force to be applied to make the enamel composition pass through the meshes in the screen via the openings corresponding to the pattern(s) to be printed, and to deposit said enamel composition on a support. The screen-printing screen must have a mesh size compatible with the size of the particles contained in the enamel composition. The filaments forming said screen may be steel filaments or filaments made of a polymeric material, for example of polyester. The number of filaments per centimeter generally varies from 120 to 180 and is preferably about 150. Preferably, the filament diameter varies from 25 to 35 μ.

The enamel composition to be screen printed is obtained by mixing the glass frit and the mineral pigment with an organic medium such as defined above. The expression “glass frit” is understood to mean an oxide-based vitrifiable composition in the form of a powder. In accordance with the process according to the invention, the glass frit is in the form of particles having a comparable size to that of the particles of pigments used in step b). Owing to the small size of its particles, in combination with a similarly low softening point, the glass frit may easily migrate toward the surface of the pane while enveloping the pigments which are thus securely and durably fixed to the glass.

The glass frit used in the process according to the invention is free of lead oxide PbO for reasons linked to protection of the environment. Preferably, the glass frit is a borosilicate based on bismuth oxide Bi₂O₃ and/or zinc oxide ZnO. For example, the Bi₂O₃-based glass frit contains 35 to 75 wt % of SiO₂ and 20 to 40 wt % of Bi₂O₃ and advantageously 25 to 30 wt %. Such a glass frit has a softening point that varies from 550 to 580° C. and preferably is equal to 568° C. For example, the ZnO-based glass frit contains 35 to 75 wt % of SiO₂ and 4 to 10 wt % of ZnO. Such a glass frit has a softening point below 600° C., which varies from 560 to 590° C., and preferably is equal to 577° C.

As already indicated, the mineral pigment included in the enamel layer has a different color from the pigment used in the layer free of glass frit and preferably imparts a color other than black. Preferably, the pigment is selected so that it has a white coloration after the firing step c). This pigment is especially titanium oxide TiO₂. Advantageously, the white mineral pigment has a lightness L*, such as defined in the CIE (1931) Lab color space, that varies from 65 to 85, as measured for the final glass pane. The pigment may be of a color other than white, and is for example based on Cr₂O₃ (green coloration), on Co₃O₄ (blue coloration) or on Fe₂O₃ (orange coloration). The proportion of pigments in the glass frit composition varies from 5 to 25 wt %, preferably 10 to 20 wt %.

The viscosity of the mixture comprising the glass frit, the mineral pigment and the organic medium generally varies from 100 to 300 poise, preferably 180 to 200 poise.

Preferably, the thickness of the enamel layer deposited on the pigment layer varies from 10 to 100 μm, preferably 20 to 80 μm.

Optionally, it is possible to apply to the enamel layer, before the firing step c), an additional layer of pigments having a color different from the pigments present in the first layer and the enamel layer. This additional Layer is generally applied so that it partially covers the surface of the enamel layer, which makes it possible to obtain relatively complex polychromatic patterns. Where appropriate, after a layer has been deposited and before the application of the following layer, it is possible to apply a heat treatment thereto with a view to reducing the amount of organic medium. The treatment temperature generally varies from 70 to 150° C., and preferably is at Least equal to 110° C. The treatment may be carried out using a method known to a person skilled in the art, for example by means of infrared lamps.

In step c) of the process according to the present invention, the glass pane is treated at a temperature referred to as the “firing temperature” which enables the glass frit to melt in order to form a layer of glass that fixes the pigment particles to the surface of the pane. In the field of enamels, the firing temperature is the minimum temperature at which a “sufficient” sintering of the enamel composition is observed, this sufficient sintering being expressed in particular by significant bonding to the glass of the pane. A person skilled in the art knows how to measure this firing temperature, for example by passing over the surface of the enamel (after the latter has been brought to the treatment temperature, then cooled) a pen comprising a metal tip connected to a spring that delivers a force of 20 newtons and by noting the lowest treatment temperature for which the enamel cannot be detached from the glass. The firing temperature must be high enough to fire the glass frit and optionally temper the glass, but not too high so that the glass sheet does not have undesirable visible deformations. In general, the firing temperature varies from 620 to 700° C., preferably from 640 to 660° C.

In the cleaning step d), the pigments that are located outside of the screen-printed patterns and which have not been fixed by the enamel are removed. The removal thereof may be carried out by any known means, for example mechanical means, especially by wiping with a cloth, dry or wet brushing or using a water jet.

The printed glass pane obtained by the process according to the invention may be used alone. In this case it is preferable for the pane to have been heat treated beforehand under temperature conditions that at least toughen and preferably temper the final glass, in order for said pane to be completely safe to use.

The glass pane obtained by the process according to the invention may be made of any type of glass, for example soda-lime-silica glass, especially obtained by the float process. As a general rule it is a glass sheet the thickness of which may vary to a large extent depending on the intended application. By way of indication, for a pane intended to be used in an architectural glazing unit, this thickness varies from 2 to 20 mm and preferably from 4 to 12 mm. Preferably, in particular for user safety reasons the glass pane is combined with one or more glass sheets, in particular corresponding to the definition given above, by means of one or more sheets of a thermoplastic having hot-melt adhesive properties so as to form a laminated glass pane. By way of example of a thermoplastic sheet, mention may be made of sheets of polyvinyl butyral butyrate (PVB), ethylene-vinyl acetate (EVA), polyurethane and polycarbonate. The number of glass sheets in the laminated pane depends on its size and on the mechanical stress to which it is subjected. In general, the laminated pane comprises at most 6 glass sheets including the printed glass pane, and preferably 2 to 4 glass sheets.

The printed pane and the glass sheets are combined with the thermoplastic sheets according to known methods, especially using an autoclave.

The invention is illustrated by means of the following nonlimiting examples and the attached figures in which:

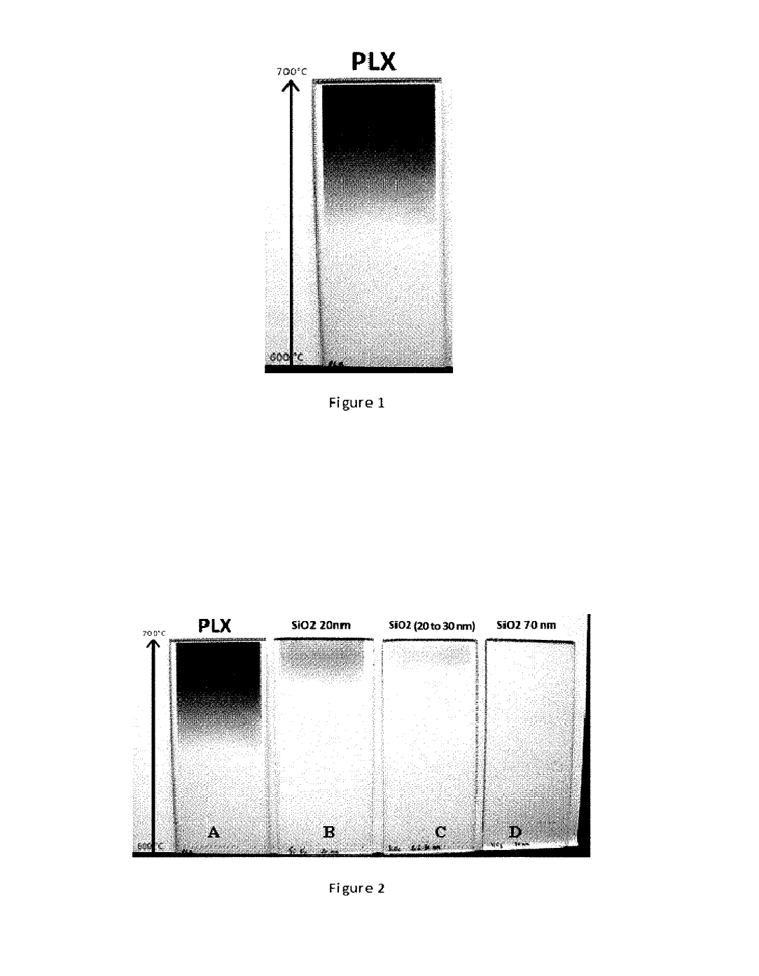

FIG. 1 represents a PLANILUX® float glass on which a black pigment has been deposited and which has undergone a firing at temperatures varying between 600 and 700° C.

FIG. 2 represents various PLANILUX® float glass substrates on which a protective layer of silicon oxide has optionally been deposited with various thicknesses.

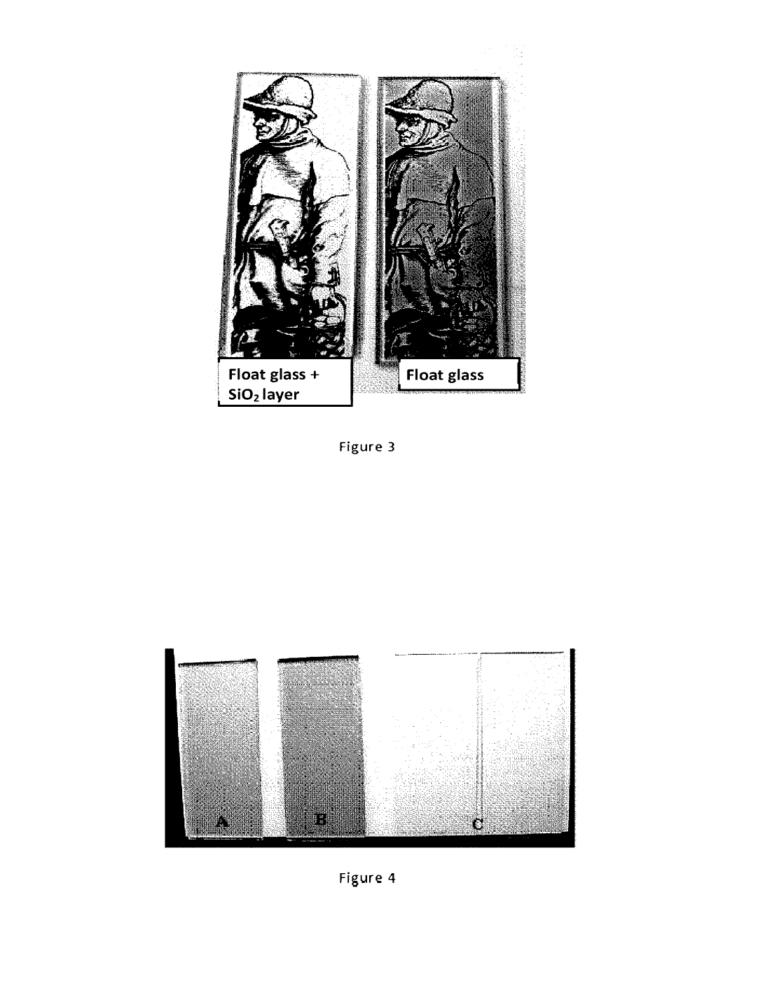

FIG. 3 represents a pattern printed on a PLANILUX® float glass substrate with or without a protective layer.

FIG. 4 represents various PLANILUX® float glass substrates on which a layer of silicon oxide has been deposited by various methods then coated with black pigments.

### EXAMPLE 1

A chromium-free black pigment is deposited by the screen-printing process using a 150.27 screen (150 being the number of filaments/cm and 27 being the thickness in pm of the polyester filament forming the screen) on a PLANILUX® glass substrate. The thickness deposited is 6 μm: it is measured using a laser perthometer just after the screen-printing step and before the drying at 140° C. Next, this substrate covered with black pigment is fired in a gradient furnace at temperatures between 600 and 700° C., and then the fired glass is cleaned.

The photo of the substrate obtained after firing and cleaning is given in FIG. 1.

A color gradient is clearly observed that is linked to the migration of the pigment toward the substrate, which migration is larger or smaller depending on the temperature.

Equivalent tests were carried out on substrates coated with a protective layer based on silicon oxide deposited with a greater or lesser thickness. FIG. 2 is a photo in which four different samples were tested.

Sample A corresponds to that which was represented in FIG. 1, as explained above. Sample B corresponds to a PLANILUX® glass substrate on which a layer of silica having a thickness of 20 nm was deposited by magnetron sputtering before depositing a black mineral pigment and carrying out a firing of the substrate thus prepared in a gradient furnace between 600 and 700° C. Sample C is identical to sample B except for the difference that the silica layer is thicker (around 25 nm). Sample D is identical to samples B and C except for the difference that the protective layer made of silica has a thickness of 70 nm. The step of depositing the black pigment is carried out under the same experimental conditions as those described above for sample A.

By comparing these various samples it is observed that the effect of the protective layer is significant: even for a thin silica layer, the gray tint decreases markedly and only appears more faintly for high firing temperatures. By increasing the thickness of the protective layer, the gray tint disappears completely even at a high firing temperature of the order of 700° C.

### EXAMPLE 2

FIG. 3 represents a printed pattern according to the process of the present invention, with or without a protective layer made of silica.

A layer of black pigment was deposited by screen printing on two different substrates 2a and 2b; the substrate 2a corresponding to a clear glass pane and the substrate 2b corresponding to a clear glass pane on which a 25 nm layer of silica was deposited by magnetron sputtering.

The screen-printing screen used is a 150.27 screen (150 filaments/cm and filaments of 27 μm). The mean thickness of the (wet) layer of black pigments deposited on the glass is equal to 6 μm. The glasses were then introduced into a drying device equipped with infrared lamps operating at a temperature of the order of 145 to 155° C. in order to remove the organic medium.

The pattern representing the person visible in FIG. 3 was then deposited by screen printing also on the two glasses containing the black pigment. The enamel used is white and is composed of a frit based on bismuth oxide and pigment based on titanium oxide. After drying of the enamel at a temperature between 145 and 155° C., the glasses were fired at a uniform standard tempering temperature (around 655° C.).

The pigments that were not fixed were removed by brushing and washing in water. The tinting of the glass was prevented with the aid of the SiO₂ protective layer previously deposited on one of the substrates.

### EXAMPLE 3

A black mineral pigment was printed on various glasses coated with a layer containing SiO₂; the process used being the same as in example 1.

The layers used were deposited by various processes (magnetron sputtering (A), chemical vapor deposition (B) “CVD” and also a combination of these two techniques (C)).

FIG. 4 represents the 3 types of layer-coated glasses on which the black pigment was deposited. The glasses were then washed and fired at a temperature of 650° C.

These various layer-coated glasses (having a layer containing SiO₂) have indeed made it possible to prevent the migration of the black pigment to the surface of the glass.

1. A process for manufacturing a one-way vision glass pane comprising one or more separate enamel patterns which comprise a number of exactly aligned layers, the process comprising:
(a) depositing at least one protective layer based on an oxide and having a thickness greater than or equal to 10 nm on a glass substrate,
(b) depositing at least two layers of different compositions on the at least one protective layer, the at least two layers comprising a layer that comprises at least one mineral pigment which layer is free of glass frit, the at least two layers further comprising a layer that comprises an enamel that comprises at least one glass frit and at least one mineral pigment having a color different from that of the layer free of glass frit, wherein the layer free of glass frit is deposited over all or some of a surface of the pane and the layer of enamel is deposited by screen printing in a shape of a desired pattern, thereby obtaining a pane coated with at least three layers,
(c) heating the pane coated with said at least three layers at a temperature sufficient to fire the enamel, and
(d) removing a portion of pigments not fixed by the enamel located outside of the pattern, thereby obtaining the one-way vision glass pane comprising one or more separate enamel patterns which comprise a number of exactly aligned layers,
wherein particles of the pigments and particles of the at least one glass frit have a similar size.

2. The process of claim 1, wherein the layer free of glass frit is deposited on the protective layer over a thickness of between 4 and 15 μm, then the layer of enamel is deposited by screen printing over a thickness of between 10 and 100 μ.m.

3. The process of claim 1, wherein the layer of enamel is deposited on the protective layer over a thickness of between 10 and 100 μm, then the layer free of glass frit is deposited over a thickness of between 4 and 30 μm.

4. The process of claim 1, wherein the protective layer deposited in the depositing (a) is a layer of silicon oxide or of titanium oxide.

5. The process of claim 4, wherein the protective layer is a layer of silicon oxide deposited by magnetron sputtering.

6. The process of claim 1, wherein the thickness of the at least one protective layer is between 10 and 150 nm.

7. The process of claim 1, wherein the depositing (a) comprises depositing two successive protective layers of different nature and thickness.

8. The process of claim 1, wherein the at least one mineral pigment in the layer free of glass frit is capable of imparting a black color after drying.

9. The process of claim 8, wherein the at least one pigment in the layer free of glass frit is based on chromium, iron, manganese, copper and/or cobalt, optionally as an oxide and/or sulfide.

10. The process of claim 1, wherein the glass frit is free of lead oxide PbO.

11. The process of claim 10, wherein the glass frit is a borosilicate based on bismuth oxide Bi₂O₃ and/or zinc oxide ZnO.

12. The process of claim 10, wherein the glass frit has a content of 35 to 75 wt % of SiO₂ and 20 to 40 wt % of Bi₂O₃ and optionally 25 to 30 wt % of ZnO.

13. The process of claim 11, wherein the glass frit comprising Bi₂O₃ if present has a softening point of from 550 to 580° C., and/or the frit comprising ZnO if present has a softening point below 600° C.

14. The process of claim 1, wherein the at least one mineral pigment of the enamel layer has a different color from the at least one mineral pigment in the layer free of glass frit.

15. The process of claim 14, wherein the at least one mineral pigment of the enamel layer is capable of imparting a white color after drying.

16. The process of claim 14, wherein the at least one mineral pigment in the enamel layer has a color other than white.

17. The process of claim 1, wherein a proportion of pigments in the composition of the enamel is from 5 to 25 wt %.

18. The process of claim 1, wherein pigment particles and particles of the at least one glass frit have a particle size distribution such that 50% of the particles have a size of less than 7 μm.

19. The process of claim 14, wherein the at least one mineral pigment of the enamel layer comprises TiO₂, Cr₂O₃, Co₃O₄, or Fe₂O₃.
